(19) United States
(12) Patent Application Publication
(10) Pub. No.: US 2004/0267864 A1
(43) Pub. Date: Dec. 30, 2004

(54) Level detection circuit, phase change detection circuit, and optical disk apparatus

(75) Inventor: Satoru Kojima, Kawaguchi-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/814,245

(22) Filed: Apr. 1, 2004

(30) Foreign Application Priority Data
Jun. 30, 2003 (JP) 2003-187023

(51) Int. Cl. H03K 5/12

(52) U.S. Cl. 708/801

(57) ABSTRACT

A level detection circuit is provided with an arithmetic unit which multiplies an input signal Vin by a value, an integration circuit which integrates the result of computation by the arithmetic unit, and a comparison unit which compares the result of integration by the integration circuit and the input signal Vin and detects a signal level change of the input value Vin.

### CROSS-REFERENCE TO RELATED APPLICATIONS

This application is based upon and claims the benefit of priority from prior Japanese Patent Application No. 2003-187023, filed Jun. 30, 2003, the entire contents of which are incorporated herein by reference.

### BACKGROUND OF THE INVENTION

1. Field of the Invention

The present invention relates to a level detection circuit, which is used in a circuit that detects a phase change in a data reproduction signal.

2. Description of the Related Art

Japanese Patent Application KOKAI Publication No. 2000-4457 (page 4, FIG. 1) discloses a circuit that detects video signal level. According to the publication, a video signal is clamped by a pedestal clamping circuit and is inverted, and the inverted signal is detected by a diode to extract only the sync signal from the video signal. The sync signal is smoothed by a capacitor and is amplified, and the level of the amplified signal is compared with a reference voltage by a comparator. Based on the comparison, whether the video signal is at the designated level is determined.

In order to detect a phase change of a data reproduction signal with fixed periodicity, an optical disk apparatus, for example, needs to detect a steep level change of the reproduction signal. In such cases, if the target level change occurs after a continuous increase of the DC level of the input signal attributable to external noise, for example, sometimes the target level change cannot be detected. This is because, conventionally, the reference voltage used for comparison is a fixed value, as described in the above-mentioned publication.

### BRIEF SUMMARY OF THE INVENTION

A level detection circuit according to one embodiment of the present invention comprises: multiplication means which multiplies an input value by a value; integration means which integrates a result of multiplication by the multiplication means; and comparison means which compares a result of integration by the integration means and the input value, and detects a signal level change of the input value.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a block diagram showing the configuration of an optical disk recording and reproducing apparatus to which the present invention is applied.

FIG. 2 shows an example of a photodetector that is divided into four.

FIG. 3 shows the structure of a track formed on an optical disk.

FIG. 4 is an enlarged view of a track.

FIGS. 5A to 5C show a track and reproduction signals thereof.

FIGS. 6A and 6B show the modulation waveform of a wobble applied to a track.

FIG. 7 is a block diagram showing the configuration of an address generating circuit 86.

FIG. 8 shows a waveform detected by the address generating circuit 86.

FIG. 9 shows the conversion of a wobble signal into digital form by an A/D converter 11.

FIG. 10 shows an integration process carried out by an integrator 12.

FIG. 11 is a block diagram showing an example of the configuration of a level detection circuit 15.

FIG. 12 shows a comparison process carried out by a comparison unit 27.

FIG. 13 shows values of multiple n when constant a is 16, constant c is 64, and b is varied from 16 to 128.

FIG. 14 shows level detection carried out by the level detection circuit 15.

### DETAILED DESCRIPTION OF THE INVENTION

An embodiment of the present invention will now be described in detail with reference to the drawings.

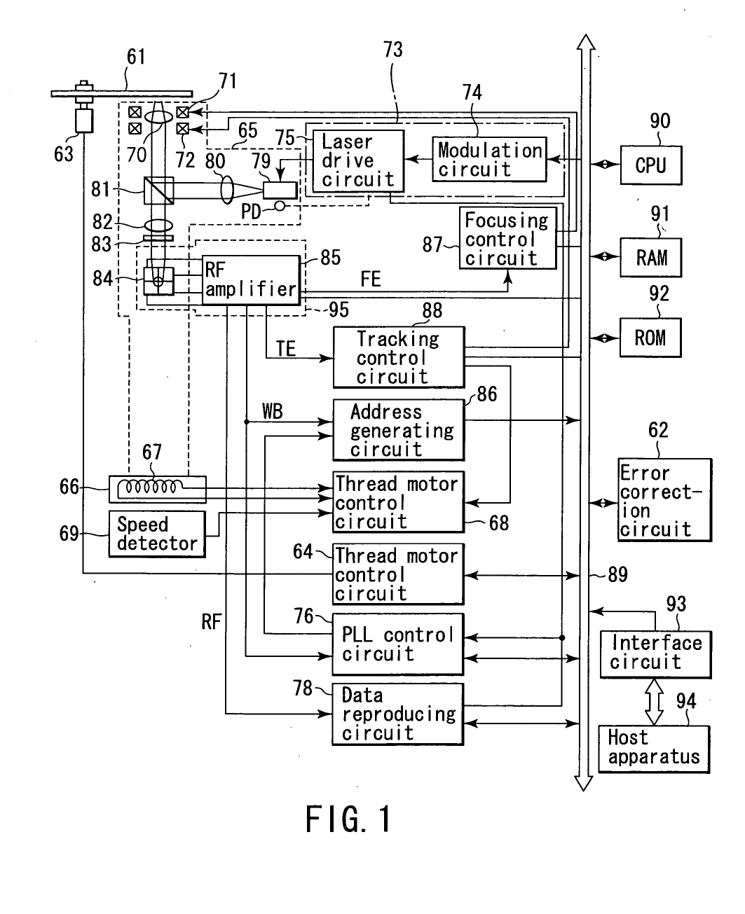

FIG. 1 is a block diagram showing the configuration of an optical disk recording and reproducing apparatus to which the present invention is applied.

A track is formed, for example, spirally on the surface of an optical disk 61 serving as a recording medium, and the disk 61 is driven to rotate by a spindle motor 63.

Data is recorded and reproduced onto and from the optical disk 61 using an optical pickup head (hereinafter referrer to as PUH) 65. The PUH 65 is connected to the optical disk apparatus body via a thread motor 66 and a gear, and the thread motor 66 is controlled by a thread motor control circuit 68.

A speed detection circuit 69 is connected to the thread motor control circuit 68, and upon detection of the speed of the PUH 65, the speed detection circuit 69 outputs a speed signal to the thread motor control circuit 68. A permanent magnet (not shown) is provided at a holding part of the thread motor 66. A driving coil 67 is energized by the thread motor control circuit 68, thereby causing the PUH 65 to move in the direction of the radius of the optical disk 61.

PUH 65 is provided with an objective lens 70 supported by a wire or blade spring (not shown). The objective lens 70 is movable in focusing directions (directions along the optical axis of the lens) when driven by a driving coil 71, and is movable in tracking directions (directions orthogonal to the optical axis of the lens) when driven by a driving coil 72.

A modulation circuit 74 provided in a laser control circuit 73, modulates data inputted from a host unit 94 through an I/F 93 and provide modulated data to a laser drive circuit 75. In response to the modulated data, a laser drive circuit 75 drives a semiconductor laser diode 79 to emits a laser beam. The laser beam emitted from the semiconductor laser diode 79 is applied onto the optical disk 61 via a collimator lens 80, a half prism 81, and the objective lens 70. The reflected light from the optical disk 61 is guided to a photodetector 84 via the objective lens 70, the half prism 81, a capasitor 82, and a cylindrical lens 83.

The photodetector 84 comprises, for example, four photo-detecting cells. The photo-detecting cells output detection signals to an RF amplifier 85. The RF amplifier 85 processes signals from the photo-detecting cells and generates a focus error signal FE indicating the difference from the in-focus state, a tracking error signal TE indicating the difference between the center of the beam spot of the laser beam and the center of the track, a wobble signal WB (to be described later) indicating the wobble of a track, and an RF signal indicating the sum of the signal values of the four photo-detecting cells.

The focusing control circuit 87 generates a focusing driving signal according to the focus error signal FE. The focusing driving signal is supplied to the driving coil 71, which moves the objective lens 70 in the focusing directions. In this way, a focus servo for keeping the laser beam continually focused on the recording film of the optical disk 61 is realized.

The tracking control circuit 88 generates a tracking driving signal according to the tracking error signal TE. The tracking driving signal output from the tracking control circuit 88 is supplied to the driving coil 72, which drives the objective lens 70 in the tracking directions. In this way, a tracking servo for causing the laser beam to continually trace the track formed on the optical disk 61 is realized.

Owing to the focus and tracking servos, the RF signal, which is a sum signal of the output signals of the photo-detecting cells of the photodetector 84, reflects changes in the reflected light from pits or record marks on the track of the optical disk 61, which are formed according to record data. The RF signal is supplied to a data reproducing circuit 78. The data reproducing circuit 78 reproduces recorded data based on a clock signal for reproduction, which is output from a PLL circuit 76.

The motor control circuit 64, the thread motor control circuit 68, the laser control circuit 73, the PLL circuit 76, the data reproducing circuit 78, the focusing control circuit 87, the tracking control circuit 88, the error correction circuit 62, and the like, are controlled by a CPU 90 via a bus 89. The CPU 90 exercises overall control over the recording and reproducing apparatus according to operation commands provided via an interface circuit 93 by a host apparatus 94. In addition, the CPU 90 performs designated control operations in accordance with programs according to the present invention, which are recorded in a ROM 92, using a RAM 91 as a work area.

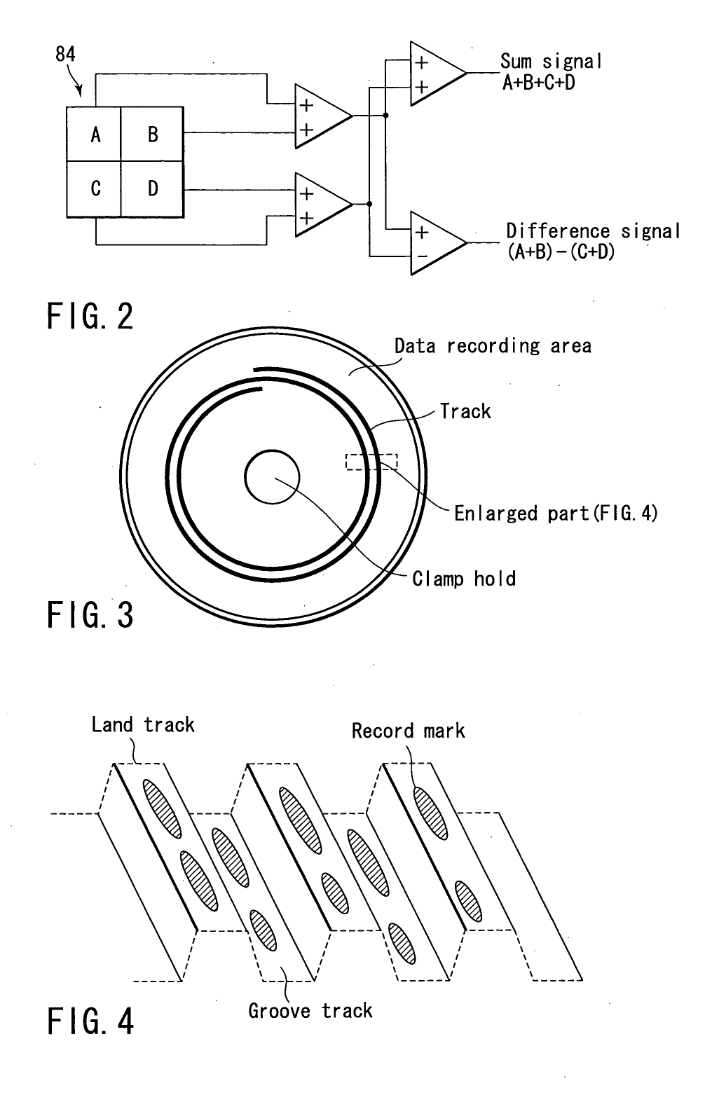

A signal obtained by adding the outputs of the cells of the photodetector 84 is called a sum signal, and a signal obtained by subtracting is called a difference signal. The RF signal is a sum signal obtained by adding high frequency data, such as user data (content made or specified by a user) and the like. FIG. 2 shows an example of a photodetector 84 that is divided into four. A sum signal RF is obtained by adding the output signals of the four cells. A difference signal is obtained by adding the output signals of two cells, thereby obtaining a sum signal, adding the output signals of the other two cells, thereby obtaining another sum signal, and subtracting one sum signal from the other sum signal.

An optical disk on which user data can be recorded, such as a DVD-RAM, DVD-RW, or DVD-R, has a guide groove in a data recording area of a data recording layer formed on a transparent substrate. The guide groove is called a track, and data is recorded and reproduced along the track. There are the spiral type, which is a continuous spiral track continuing from the inner side to the outer side as shown in FIG. 3, and the concentric type comprising a series of concentric circular tracks (not shown).

FIG. 4 shows an enlarged view of a track. A track is made of depressed parts and projected parts of the data recording layer; the former are called grooves and the latter are called lands. For example, on a DVD-RAM or next-generation recordable optical disk, data is recorded in the form of record marks on both the lands and the grooves, thereby increasing the data storage density in the radial direction.

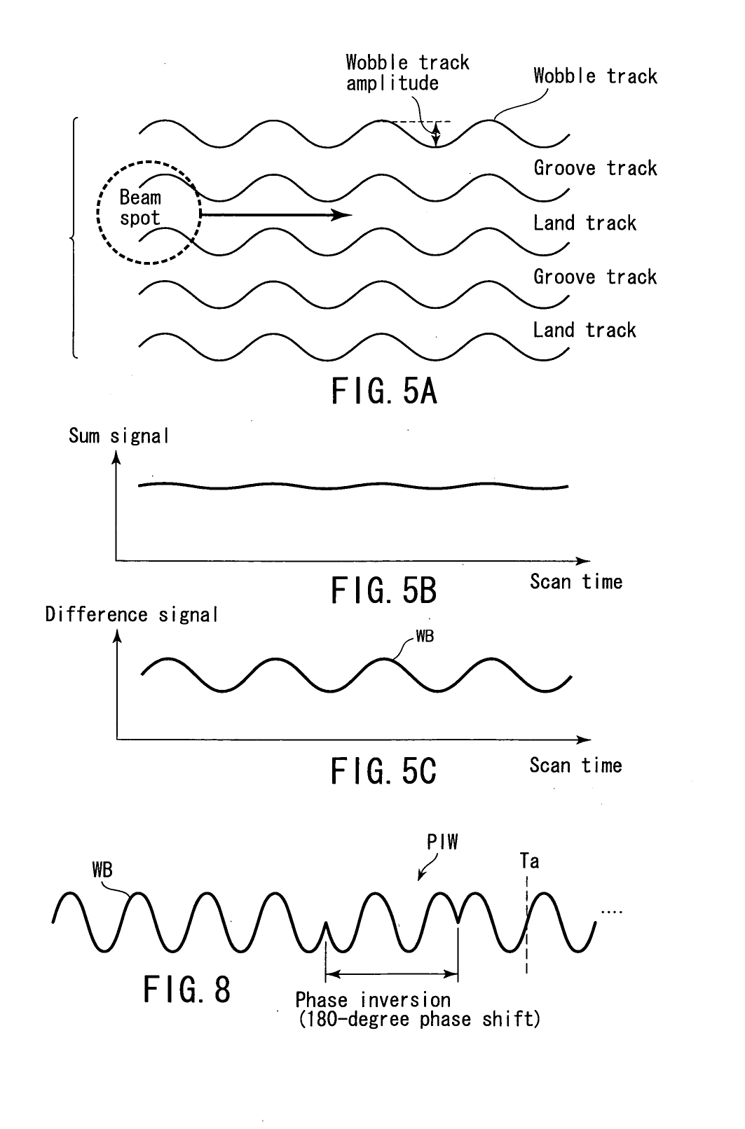

FIG. 5A shows a track as viewed from above. A track on an optical disk, according to the present invention, slightly meanders in the radial direction. Such a track is called a wobble track. If an optical disk is scanned with a beam spot of focused light along this wobble track, the beam spot moves in a substantially straight line at the center of the wobble track. This is because the wobble track has a higher frequency than the frequency band of the tracking servo signal. The sum signal scarcely fluctuates at that time, as shown in FIG. 5B. As shown in FIG. 5C, only the difference signal in the radial direction fluctuates with the wobble. In this manner, the difference signal of a recordable optical disk reflects the wobble of the track and hence is called a wobble signal WB hereinafter. The wobble signal WB is used for adjustment of the rotational frequency of the spindle, and as the reference for the recording clock, and as physical address information.

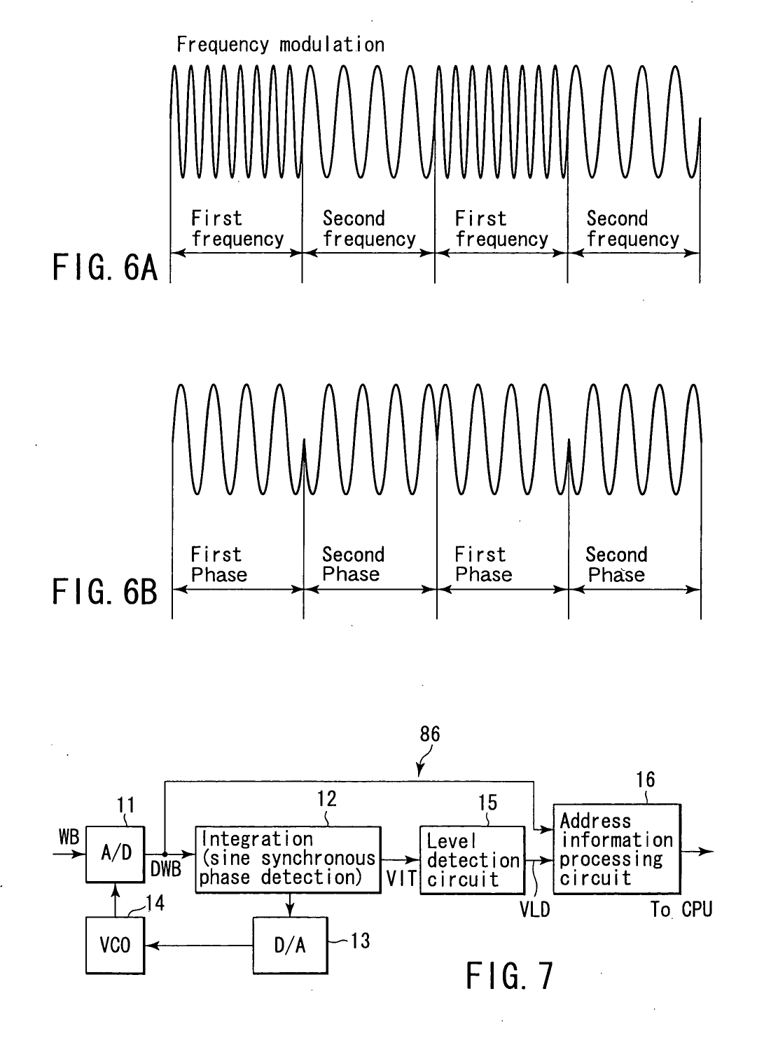

Physical address information, which indicates a physical location in the data recording area of a recordable optical disk, is recorded by modulating the wobble. In other words, physical address information is recorded by subjecting a wobble, which is to be applied to the track, to frequency modulation or phase modulation such as the one shown in FIGS. 6A and 6B. Both the signals shown in FIGS. 6A and 6B represent, for example, 1010.

The address generating circuit 86 processes the wobble signal WB, thereby reading the physical address information indicating the location of the part of the optical disk 61 that is irradiated with the laser beam, and outputs the result to the CPU 90. Based on the address information, the CPU 90 records data such as user data at a desired location, and reads data such as user data recorded at a desired location.

FIG. 7 is a block diagram showing the configuration of the address generating circuit 86.

The address generating circuit 86 includes an A/D converter 11, an integrator 12, a D/A converter 13, a voltage control oscillator (VCO) 14, a level detection circuit 15, and an address information processing circuit 16. If the address generating circuit 86 receives a wobble signal WB, such as the one shown in FIG. 8, it detects the part where the phase is changed (PIW), and extracts the address information contained in the wobble signal WB behind the PIW. The wobble signal WB is a continuous sine wave with fixed periodicity and amplitude, in which a two-period long signal PIW with an inverted phase (180-degree phase shift) is inserted.

The wobble signal WB contains an address signal after a point Ta which is a point, for example, one period after the signal PIW as shown in FIG. 6. The inverted signal PIW is used as a trigger for extracting an address signal.

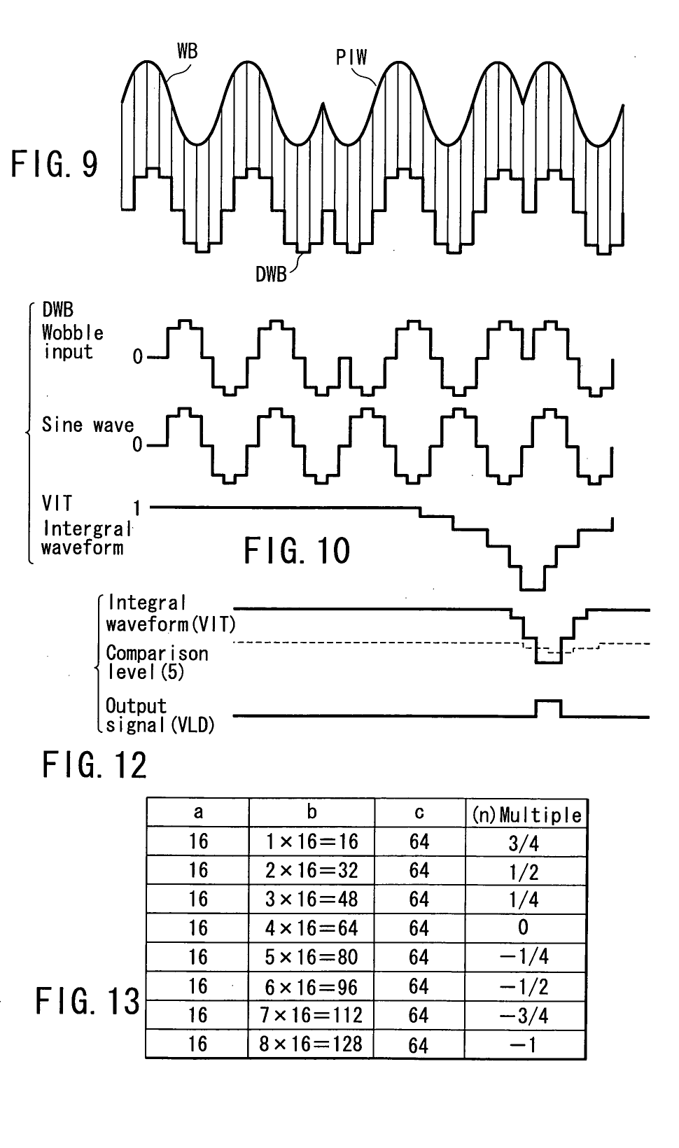

As shown in FIG. 9, the A/D converter 11 converts the wobble signal WB into a digitalized wobble signal DWB based on a sampling clock input from the VCO 14. In this example, the A/D converter 11 samples the wobble signal WB every ⅛ of the period of the wobble signal WB. The wobble signal DWB is expressed in 2's complement (a binary number having a sign bit that indicates negative or positive).

The integrator 12 generates an integral signal VIT from the wobble signal DWB. FIG. 10 shows the generation of an integral signal VIT from the wobble signal DWB in terms of waveform. The integrator 12 multiplies the wobble input DWB by a sine wave and integrates the result of the multiplication to generate an integral signal VIT. The sine wave has the same period as the wobble signal WB, and is produced by digitalizing a reference sine wave having an amplitude of 1. The reference sine wave is obtained from the PLL control circuit 76. The input signal to the D/A converter 13 is almost the same as the signal VIT but is modified according the input and output characteristics of the D/A converter 13.

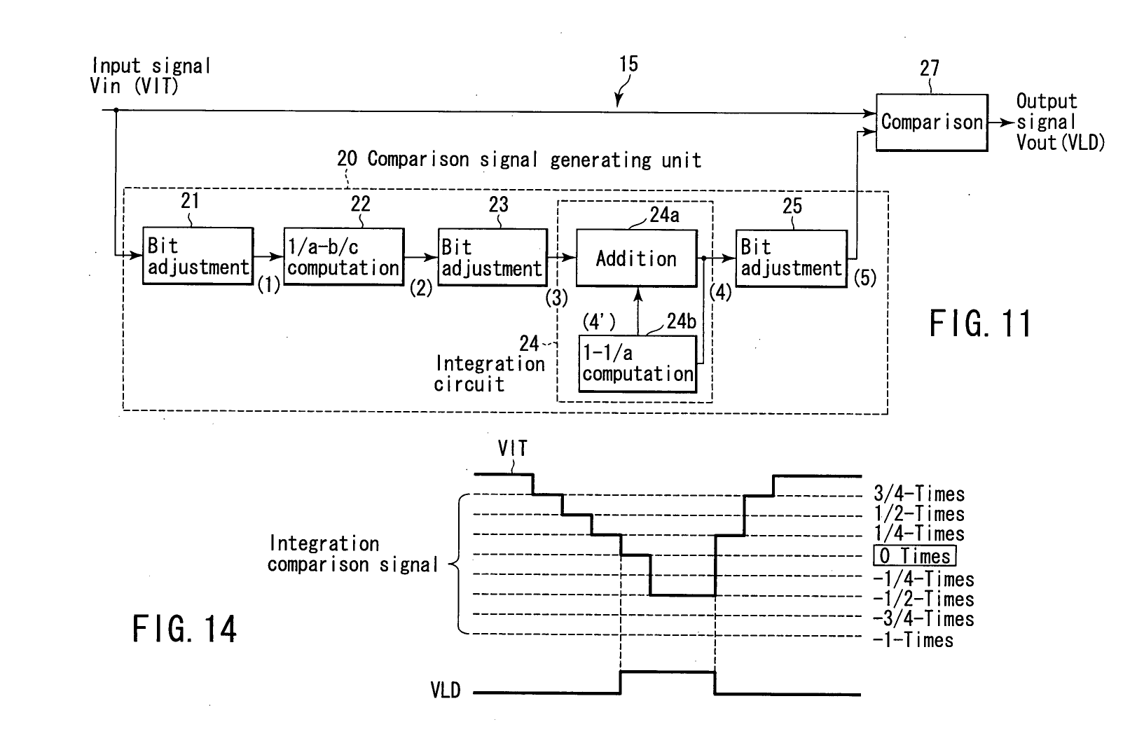

The level detection circuit 15 detects a steep level change of the integral signal VIT, i.e., the signal PIW corresponding to the part of the wobble signal WB where the phase is inverted (shifted 180 degrees). FIG. 11 is a block diagram showing an example of the configuration of the level detection circuit 15. The level detection circuit 15 includes a comparison signal generating unit 20 and a comparison unit 27. The comparison signal generating unit 20 includes a bit adjustment unit 21, an arithmetic unit 22, another bit adjustment unit 23, an integration circuit 24, and yet another bit adjustment unit 25.

The operation of the comparison signal generating unit 20 will now be described using the integral signal VIT as an input signal having an amplitude Vin. The comparison signal generating unit 20 integrates a value equal to n times the input signal Vin, and outputs the result of integration as a comparison signal (5).

The bit adjustment unit 21 carries out bit expansion for improving computation accuracy during the arithmetic operation carried out at a subsequent stage, i.e., increases the number of bits of the input signal Vin. If the input signal Vin is positive, the bit adjustment unit 21 adds 0 to the most significant bit. If the input signal Vin is negative, the bit adjustment unit 21 adds 1 to the most significant bit. The bit adjustment unit 21 changes the number of bits of the input signal Vin but does not cause a substantial change in the numerical value. Therefore, the output signal (1) of the bit adjustment unit 21 is Vin.

The arithmetic unit 22 multiplies the input signal (1) by 1/a−b/c, wherein 1/a is for adjusting the integral value output at a subsequent stage of the integral circuit 24, so that the output integral value does not exceeds the input signal; and b, and c are arbitrary numbers for establishing value n in the “n times the input signal Vin”. Each of a, b, and c is, for example, an nth power of 2, which is obtained experimentally from the characteristics of the input signal Vin. The output signal (2) of the arithmetic unit 22 is as follows:

$$Vin ( \frac{1}{a} - \frac{b}{c} ) \qquad ( 2 )$$

The bit adjustment unit 23 carries out bit deletion according to need in order to simplify the result of multiplication, for example, when overflow (carry) is caused by the multiplication of 1/a−b/c. Therefore, the output signal (3) of the bit adjustment unit 21, below, is substantially the same as (2):

$$Vin ( \frac{1}{a} - \frac{b}{c} ) \qquad ( 3 )$$

The integral circuit 24 includes an adder 24a and an arithmetic unit 24b. The arithmetic unit 24b multiplies the output signal of the adder 24a by 1−1/a. The adder 24a adds signal (3) and multiplication result (4′) output from the arithmetic unit 24b.

The addition result (output signal (4)) output from the adder 24a changes every time an arithmetic operation is carried out, for example, as follows:

$$\begin{matrix}\text{First:} Vin ( \frac{1}{a} - \frac{b}{c} ) \\ \text{Second:} Vin ( \frac{1}{a} - \frac{b}{c} ) \{ ( 1 - \frac{1}{a} + 1 ) \} \\ \text{Third:} Vin ( \frac{1}{a} - \frac{b}{c} ) \{ {( 1 - \frac{1}{a} )}^{2} + ( 1 - \frac{1}{a} ) + 1 \}\end{matrix}$$

Therefore, the addition result of the adder 24a, i.e., the output signal (4) of the integration circuit 24, is obtained as follows:

$$Vin ( \frac{1}{a} - \frac{b}{c} ) \{ {( 1 - \frac{1}{a} )}^{m} + {( 1 - \frac{1}{a} )}^{m - 1} + {( 1 - \frac{1}{a} )}^{m - 2} … + 1 \} \qquad ( 4 )$$

The bit adjustment unit 25 carries out bit truncation so that two signals that are input at a subsequent stage to the comparison unit 27 during the comparison operation will have the same number of bits. In other words, the bit adjustment unit 25 reduces the number of bits, which has been increased by the bit adjustment unit 21, so that it is equal to that of the input signal Vin. Therefore, the output signal (5) of the bit adjustment unit 25, below, is the same as signal (4):

$$Vin ( \frac{1}{a} - \frac{b}{c} ) \{ {( 1 - \frac{1}{a} )}^{m} + {( 1 - \frac{1}{a} )}^{m - 1} + {( 1 - \frac{1}{a} )}^{m - 2} … + 1 \} \qquad ( 5 )$$

The comparison unit 27 compares the input signal Vin (i.e., the integral waveform VIT) and the output signal (5) of the bit adjustment unit 25, and outputs an output signal Vout as a comparison result, as shown in FIG. 12. The output signal Vout is the signal VLD shown in FIG. 7. In this example, the timing of outputting the VLD (H-level period) is the period when the level of the input signal Vin drops below the comparison level (5). The period corresponds to the timing of appearance of the signal PIW, shown in FIG. 9 or 8, having a phase that corresponds to an inverted phase (shifted 180 degrees) of the wobble signal WB. In this way, a phase change of the wobble signal WB is determined based on the signal VLD.

FIG. 13 shows values of multiple n when constant a is 16, constant c is 64, and b is varied from 16 to 128. Note that b represents values obtained by multiplying integers between 1 to 8 by 16. Multiple n represents values of convergence obtained through multiple integration operations by the integration circuit 24.

In other words, the comparison signal generating unit 20 outputs the integral of the value obtained by multiplying the input signal Vin by multiple n, as a comparison signal (5). Note that the values of a, b, and c actually used in a disk drive system such as the one shown in FIG. 1 are decided most suitably according to the characteristics of the system, as stated above.

FIG. 14 shows the manner in which level detection is performed by the level detection circuit 15, and illustrates the time when the VIT is expressed in 2's complement. A comparison signal level that is n times (¾ times, . . . , −1 times) the input signal is generated by adjusting the values of b and c, as shown in FIG. 13. FIG. 14 shows an integral comparison signal when “0 times” (0 level) is selected. In other words, it shows the case where the comparison result (VLD) becomes 1 when the level of the input signal becomes 0 or less.

The present embodiment, described above, has the following advantages:

1. Because level detection uses a comparison signal obtained by integrating the value equal to n times the input signal, a correct reference signal level that follows the input signal can be detected.

2. The use of multiplication and addition enables generation of a comparison signal less affected by disturbances such as noise.

3. An increase in the number of bits at the time of generating a comparison signal (5) allows the multiplication by n to produce a more accurate result.

4. A comparison signal can be generated which is either positive or negative with respect to DC level of the input signal.

5. The input signal may be either an absolute value or in 2's complement (the presence or absence of a sign is irrelevant).

Referring back to FIG. 7, the address information processing unit 16 demodulates the address signal from the wobble signal WB after the point Ta which is, for example, at one period of the wobble signal WB after the leading edge of the signal VLD, and transfers the address signal to the CPU 90.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A level detection circuit that detects a level change of a input value, comprising:
a multiplication unit which multiplies the input value by a value;
an integration unit which integrates a result of multiplication by the multiplication unit; and
a comparison unit which compares a result of integration by the integration unit with the input value, and detects a level change of the input value.

2. A level detection circuit according to claim 1, wherein the multiplication unit multiplies the input value by 1/a−b/c, wherein a, b, and c are arbitrary numbers, and
the integration unit includes an adder unit, and an arithmetic unit which multiplies a result of addition by the adder unit by 1-1/a, the adder unit adding a result of multiplication by the multiplication unit and a result of computation by the arithmetic unit.

3. A level detection circuit according to claim 2, wherein the input value, a, b, and c are binary numbers, and the level detection circuit further comprises:
a first bit adjustment unit which adjusts the number of bits of the input value input to the multiplication unit; and
a second bit adjustment unit which adjusts the number of bits of the result of integration such that the number of bits of the result of integration equals the number of bits of the input value when the result of integration and the input value are compared by the comparison unit.

4. A phase change detection circuit that detects a phase change of an input signal, comprising:
a sine wave generating circuit which generates, from the input signal, a reference sine wave having the same period as the input signal;
a first integration unit which multiplies the input signal by the reference sine wave, integrates a result of the multiplication, and provides a first integration result;
a multiplication unit which multiplies the first integration result by a value, and provides a multiplication result;
a second integration unit which integrates the multiplication result, and provides a second integration result; and
a comparison unit which detects a level change of the first integration result as a phase change of the input signal by comparing the first integration result and the second integration result.

5. A phase change detection circuit according to claim 4, wherein the multiplication unit multiplies the input value by 1/a−b/c where a, b, and c are arbitrary numbers,
the second integration unit includes an adder unit, and an arithmetic unit which multiplies a result of addition by the adder unit by 1-1/a, and
the adder unit adds the multiplication result provided by the multiplication unit and a result of computation by the arithmetic unit.

6. A phase change detection circuit according to claim 5, wherein the input value, a, b, and c are binary numbers, and the phase change detection circuit further comprises:
a first bit adjustment unit which adjusts the number of bits of the input value input to the multiplication unit; and
a second bit adjustment unit which adjusts the number of bits of the second integration result such that the number of bits of the second integration result equals the number of bits of the input value when the second integration result and the input value are compared by the comparison unit.

7. An optical disk comprising:
a wobble signal generating unit which generates a wobble signal from reflected light from a track on an optical disk on which a wobble, modulated using an address signal, is formed;
a sine wave generating unit which generates, from the wobble signal, a reference sine wave having the same period as the wobble signal;
a first integration unit which multiplies the wobble signal by the reference sine wave, integrates a result of multiplication, and provides a first integration result;
a level detection unit which detects a level change of the first integration result as a phase change of the wobble signal; and
an address extraction unit which extracts the address signal from the wobble signal in response to detection of the phase change,
wherein the level detection unit comprises:
a multiplication unit which multiplies the first integration result by a value, and provides a multiplication result;
a second integration unit which integrates the multiplication result, and provides a second integration result; and
a comparison unit which compares the first integration result and the second integration result, and detects a signal level change of the first integration result.

8. An optical disk according to claim 7, wherein the multiplication unit multiplies the input value by 1/a−b/c, wherein a, b, and c are arbitrary numbers, and
the integration unit includes an adder unit, and an arithmetic unit which multiplies a result of addition by the adder unit by 1−1/a, the adder unit adding the multiplication result provided by the multiplication unit and a result of computation by the arithmetic unit.

9. An optical disk apparatus according to claim 8, wherein the input value, a, b, and c are binary numbers, and the phase change detection circuit further comprises:
a first bit adjustment unit which adjusts the number of bits of the input value input to the multiplication unit; and
a second bit adjustment unit which adjusts the number of bits of the second integration result such that the number of bits of the second integration result equals the number of bits of the input value when the second integration result and the input value are compared by the comparison unit.
